(19) United States
(12) Patent Application Publication
(10) Pub. No.: US 2010/0066520 A1
(43) Pub. Date: Mar. 18, 2010

(54) DISPLAY

(75) Inventors: Gerhard Kammerer, Konigsbach (DE); Manfred Suss, Remchingen (DE); Cedric Cheveau, Paris (FR); Jöel Fournier, Cregy (FR)

Correspondence Address: DICKINSON WRIGHT PLLC, 1875 Eye Street, NW, Suite 1200, WASHINGTON, DC, 20006, US

(73) Assignee: JOHNSON CONTROLS AUTOMOTIVE ELECTRONICS GMBH, Remchingen (DE)

(21) Appl. No.: 12/063,441

(22) PCT Filed: Aug. 11, 2006
(86) PCT No.: PCT/EP2006/007986

§ 371 Date: Dec. 3, 2009

(30) Foreign Application Priority Data
Aug. 11, 2005 (EP) 05017537.1

(51) Int. Cl. B60Q 1/00; H01J 1/62

(52) U.S. Cl. 340/438; 313/504

(57) ABSTRACT

The display and/or lighting for the interior of a vehicle comprising at least two stacked layers each comprising at least one OLED.

### CROSS REFERENCE TO RELATED APPLICATIONS

None.

### FIELD OF THE INVENTION

The present invention relates to the display and/or lighting for the interior of a vehicle comprising at least two stacked layers each comprising at least one OLED.

### BACKGROUND

In order to come up with new designs for instrument panels, new illumination systems are needed. U.S. Pat. No. 6,291,788 B1, DE 100 52 580 A1, DE 197 08 610 A1, DE 199 03 201 A1 and DE 101 39 001 A1 suggest indicating instruments which are illuminated by an organic light emitting diode (OLED). However, these illuminations have the disadvantage, that the illumination is in many cases not bright enough, not long lasting enough and/or that a multicolour-display can not be realized.

It is therefore the objective of the present invention to overcome the disadvantages of the displays and/or lighting systems characteristic of the state of the art.

### SUMMARY OF THE INVENTION

The problem is solved with a display and/or a lighting for the interior of a vehicle comprising at least two stacked layers each layer comprising at least one OLED.

A display and/or lighting according to this invention exhibits increased durability of the illumination of a display or the lighting, increased intensity of the illumination of a display or the lighting, the ability to realize several different colours, the ability to change the colour of the display and/or the lighting, and the ability to orient several colours side by side without mixing zones.

According to the present invention, the display and/or lighting comprises at least two stacked layers. These layers comprise at least one OLED which at least partially, preferably entirely, overlap, so that the OLEDs are at least partially stacked upon each other.

An organic light emitting diode (OLED) is a thin film light emitting diode, in which the emissive layer is an organic compound. This layer is placed between two conductors.

After an electrical current is applied, a bright light is emitted. These systems are very thin, usually less than 500 nm. The films are flexible and can therefore be used for almost arbitrarily shaped displays or lightings. When used to produce displays, OLED technology produces self-luminous displays that do not require back lighting. These properties result in thin, very compact displays. These displays also have a wide viewing angle up to 160 [deg.] and require very little power, only 2-10 volts.

According to the present invention, the display comprises two layers, each layer comprising at least one OLED, which are stacked upon each other. Preferably, the OLED in each layers are identical. This preferred embodiment of the present invention has the advantage, that the brightness of the display and/or lighting can be increased if the OLEDs in all layers are activated. If the OLED is only activated in one layer, the durability of the display can be increased; i. e. after the OLED in one layer has failed, the OLED in the other layer will be activated. Both layers can be activated with half power which increases the lifetime.

In an other preferred embodiment of the present invention, the OLEDs in the two layers are partially identical. This embodiment of the present invention has the advantage, that a multicolour display which comprises at least two different colours can be realized. Identical according to the present invention means that the OLEDs are identical in size and colour.

According to another preferred embodiment of the present invention at least one layer comprises two OLEDs which are different from each other. This preferred embodiment of the present invention allows to realize multicolour displays with very sharp boundaries between the different colours.

In a preferred embodiment of the present invention, the OLEDs of only one layer are activated.

In another preferred embodiment of the present invention all OLEDs in the different layers are activated. Preferably, the display according to the present invention is combined with LED- or OLED-symbols. A symbol according to the present invention is any symbol used in the instrumentation panel of a car.

Preferably, if not activated, the two stacked layers appear as a black background. This is for example achieved by a circular polarizer. This preferred embodiment of the present invention has the advantage, that the OLEDs which are normally transparent in a non-activated condition appear as a black background.

Preferably, at least one of the OLED layers comprises a reflecting zone, so that all light emitted by the OLEDs is directed into one direction.

Another embodiment of the present invention is a transparent information display comprising information displaying means with a first and a second surface, whereas the second surface is at least partially covered by an OLED.

The inventive information display is transparent as long as the OLEDs are not activated. Thus, the inventive display has the advantage, that during daytime, the display does not reduce the field of view and that during night-time the display can be illuminated by the OLED. It can display any kind of information important for the passengers in the vehicle.

Preferably, the inventive display comprises two layers of OLEDs.

In another preferred embodiment the inventive display comprises LED and/or OLED symbols to display any information needed to conduct a vehicle.

Since the display is transparent, it can be mounted on top of the dash board of a vehicle without limiting the field of vision during the daytime. The invention is now explained with FIGS. 1-8. These explanations do not limit the scope of protection of the present invention.

### BRIEF DESCRIPTION OF THE DRAWINGS

These and other features and advantages of the present invention will become more readily appreciated when considered in connection with the following detailed description and appended drawings, wherein:

FIG. 1 shows one embodiment of the present invention with two identical OLEDs.

FIG. 2 shows another embodiment of the present invention with two different layers of OLEDs.

FIG. 3 shows an embodiment of the present invention wherein each layer comprises several OLEDs.

FIG. 4 shows an embodiment of the present invention with LED symbols on the display.

FIG. 5 shows an embodiment of the present invention with a circular polarizer and a mirror.

FIG. 6 shows a transparent display.

FIG. 7 show the front-view of the display according to FIG. 6.

FIG. 8 show the front-view of the illumination of the display according to FIG. 6.

### DETAILED DESCRIPTION OF THE PREFERRED EMBODIMENTS

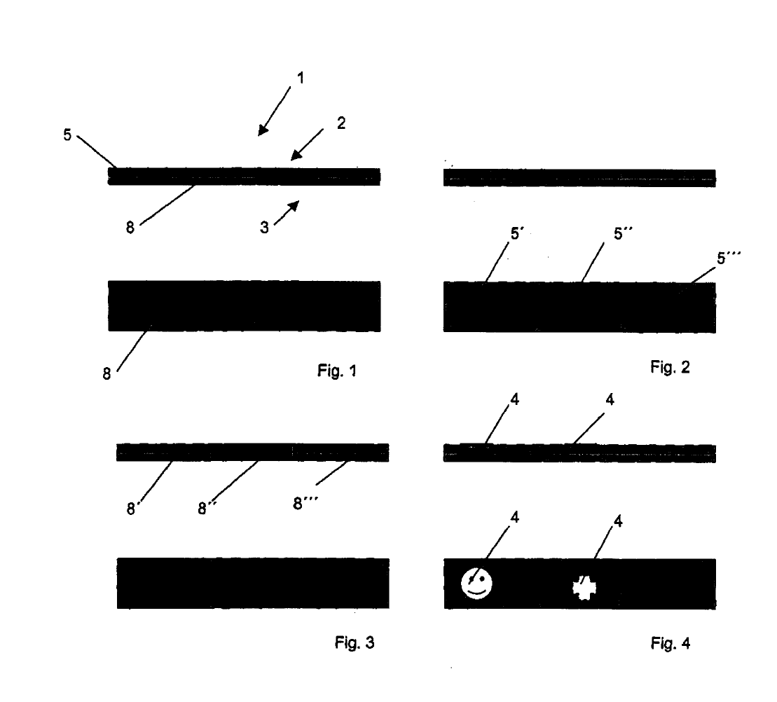

Referring to the Figures, wherein like numerals indicate like or corresponding parts throughout the several views, FIG. 1 shows one embodiment of the inventive display 1 which comprises an upper layer 2 and a lower layer 3, whereas layer 2 comprises OLED 5 and layer 3 OLED 8. Both layers and thus the OLEDs are arranged on a support (not depicted). In the present example, the two OLEDs 5, 8 are identical in size and emit the same light frequencies; i.e. the same colours. The OLED 5 and the OLED 8 can be activated independently. This embodiment of the present invention has the advantage that the durability of the illumination can be prolonged if only one OLED is activated. As soon as this OLED fails, the other OLED will be automatically activated or both OLEDs are activated with half power which increases the lifetime. On the other hand, both OLEDs 5,8 can be activated simultaneously with full power which increases the brightness of the illumination.

In FIG. 2 another embodiment of the inventive display and/or illumination is shown in two views. In the present example, the lower OLED is in comparison to the example according to FIG. 1 unchanged while FIG. 2 comprises three OLEDs 5′-5′″. The OLED 5′ emits the same light frequency as OLED 8 in layer 3 while OLED 5′ emits a light with a different colour in comparison to the other OLEDs. If only the OLEDs in layer 2 are activated, a display and/or a illumination with three different colour zones is possible, whereas the boundary between the different zones is very sharp. If only the OLED 8 is activated, a uniformly coloured display is achieved. When OLEDs in both layers are activated, again a display with three zones, is achieved, whereas the light emissions in zone 5′ and 5′″ is increased and in zone 5″ a colour resulting from the mixture of the colours of OLED 5″ and OLED 8 is displayed.

FIG. 3 essentially shows an example of a present invention which is similar to an example according to FIG. 1 with the difference that three distinct colour zones can be seen on the display. The OLEDs in layer 2 and 3 can be activated separately or simultaneously as already explained in the example according to FIG. 1.

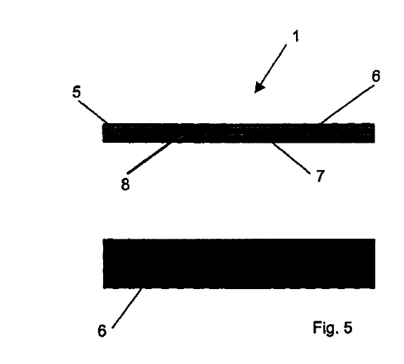

In the example according to FIG. 4, the display according to FIG. 2 is combined with OLED or LED symbols which can be activated independently of the OLEDs according to layer 2 or 3. The symbols 4 can contain any information needed in a display of a vehicle, preferably an automobile.

In FIG. 5 another example of an embodiment of the present invention is shown. In this example, the two layers 2, 3 comprise at the bottom a mirror 7 which reflects all the emitted light into one direction. On top, the inventive display according to the present example has a circular polarizer 6 so that the displays, if not activated, appear as a black surface. The person skilled in the art understands that the mirror and the circular polarizer can also be combined with the embodiments of the present invention according to FIGS. 1-4.

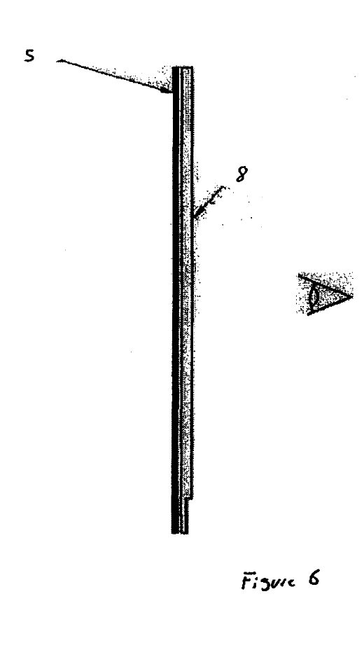

FIG. 6 shows another embodiment of the inventive display. On its front-side, the side that is directed towards the viewer, it comprises a display 8 on which several symbols can be seen. On its backside the display comprises one or more OLEDs, which can be partially stacked and which illuminate the display. Besides the symbols, the display is totally transparent, as long as the OLEDs are not activated, for example during daytime.

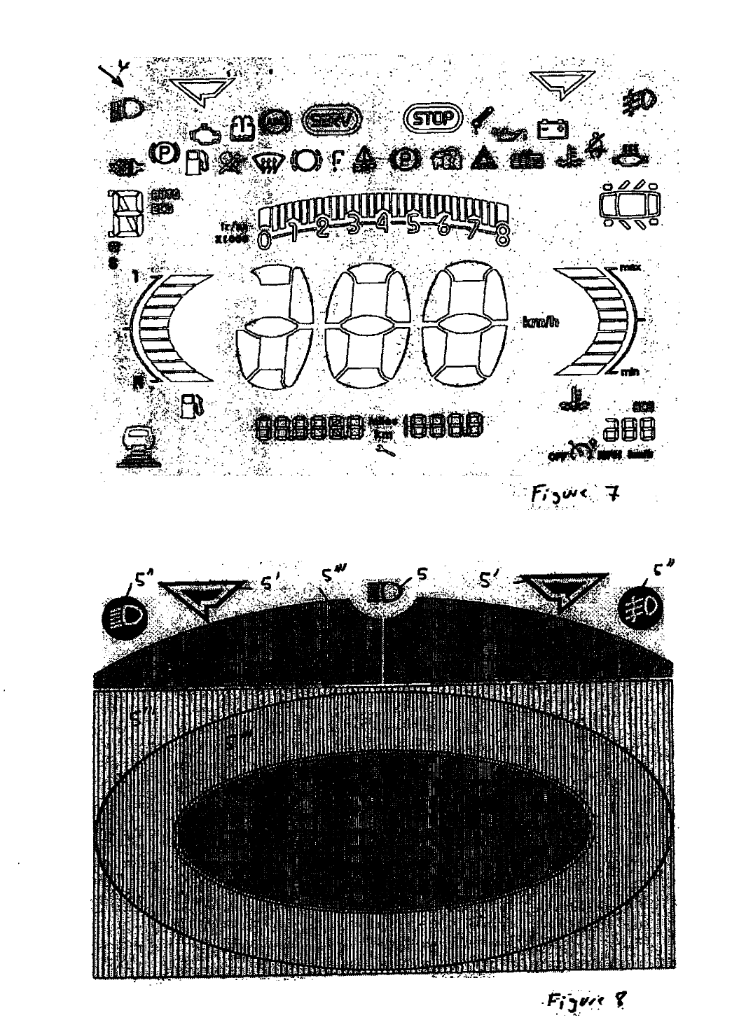

FIG. 7 shows the front-side of the display according to FIG. 6, which comprises several distinct symbols 4, which depict important information for the operation of a vehicle. The symbols are at least partially LCD-Symbols.

FIG. 8 shows the backside of the display according to FIG. 6. It comprises several OLEDs 5<′>-5<′″>, which serve as the illumination for the display. The OLEDs illuminate distinct symbols and/or areas. The OLEDs can be stacked in order to achieve the advantages as described above.

The foregoing invention has been described in accordance with the relevant legal standards, thus the description is exemplary rather than limiting in nature. Variations and modifications to the disclosed embodiment may become apparent to those skilled in the art and fall within the scope of the invention. Accordingly the scope of legal protection afforded this invention can only be determined by studying the following claims.

Reference list

1 Display, lighting 2,3 layer

2 LED-, OLED-symbols, symbols 5, 5′,5″,5′″ OLEDs

6 Circular polarizer

7 Mirror

8 front-side of the display

1. A transparent information display (8) having a first and a second surface,
and wherein the second surface is at least partially covered by an OLED.

2. The display (8) according to claim 1, wherein the second surface is at least partially covered with two layers of OLED (9, 10).

3. The display (8) according to claim 1, further including LED- and/or OLED-Symbols (4).

4. The display (8) according to claim 1, wherein the display is mounted on top of a dash board of a vehicle.

5. A display (1) and/or lighting for the interior of a vehicle, said display and/or lighting comprising at least two stacked layers (2, 3), each stacked layer comprising at least one OLED (5, 5<′>, 5<″>, 5<′″>).

6. The display and/or lighting according to claim 5, wherein the OLEDs (5, 5<′>, 5<″>, 5<′″>) in each stacked layer are identical to one another.

7. The display according to claim 5, wherein the OLEDs (5, 5<′>, 5<″>, 5<′″>) in each stacked layer are at least partially identical to one another.

8. The display according to claim 5, wherein at least one layer (2, 3) comprises at least two OLEDs (5, 5<′>, 5<″>, 5<′″>), which are different from one another.

9. The display according to claim 5, wherein the OLED (5, 5<′>, 5″, 5<′″>) in one stacked layer (2, 3) is activated while the OLED in the other stacked layer is not activated.

10. The display according to claim 5, wherein the OLED in both stacked layers (2, 3) are simultaneously activated.

11. The display according to claim 5, further including LEDs-symbols (4).

12. The display according to claim 5, further including OLEDs-symbols (4).

13. The display according to claim 5, further including a circular polarizer (6).

14. The display according to claim 5, further including a mirror (7).
